(19) United States
(12) Patent Application Publication
(10) Pub. No.: US 2025/0070012 A1
(43) Pub. Date: Feb. 27, 2025

(54) SEMICONDUCTOR PACKAGE

(71) Applicant: SAMSUNG ELECTRONICS CO., LTD., Suwon-si (KR)

(72) Inventors: Juhyung Lee, Suwon-si (KR); Sunchul Kim, Suwon-si (KR)

(21) Appl. No.: 18/672,532

(22) Filed: May 23, 2024

(30) Foreign Application Priority Data
Aug. 24, 2023 (KR) 10-2023-0111514

(51) Int. Cl. H01L 23/498; H01L 23/00; H01L 23/13; H01L 23/31; H01L 23/42; H01L 25/10

(52) U.S. Cl. CPC H01L 23/49838; H01L 23/13; H01L 23/3128; H01L 23/42; H01L 25/105; H01L 24/08; H01L 24/16; H01L 24/48; H01L 24/73; H01L 2224/08225; H01L 2224/16227; H01L 2224/48227; H01L 2224/73257; H01L 2225/1023; H01L 2225/1058; H01L 2924/1815

(57) ABSTRACT

The present disclosure relates to semiconductor packages and semiconductor package manufacturing methods. An example semiconductor package includes a first package substrate, a first semiconductor chip on the first package substrate, an interposer on the first semiconductor chip, a support substrate on the first package substrate and spaced apart from a sidewall of the first semiconductor chip, a conductive filler on the support substrate, a connection bump between the support substrate and the interposer and electrically connecting the conductive filler with the interposer, and a first molding layer surrounding the sidewall of the first semiconductor chip and a sidewall of the connection bump.

### CROSS-REFERENCE TO RELATED APPLICATION

This application claims priority under 35 U.S.C. § 119 to Korean Patent Application No. 10-2023-0111514, filed on Aug. 24, 2023, in the Korean Intellectual Property Office, the disclosure of which is incorporated by reference herein in its entirety.

### BACKGROUND

With the rapid development of the electronics industry and users' needs, electronic devices have become more compact, multi-functional, and high-capacity. Accordingly, a semiconductor package including a plurality of semiconductor chips is required. Although high integration density of semiconductor chips of a semiconductor package is desired, the high integration density may not be frequently achieved with printed circuit boards. Therefore, a semiconductor package for connecting semiconductor chips to each other by using an interposer has developed.

### SUMMARY

The present disclosure relates to semiconductor packages, including a semiconductor package including an interposer.

Aspects of the present disclosure are not limited to those mentioned above, and other aspects will be clearly understood by one of skill in the art from the description below.

In some implementations, a semiconductor package includes a first package substrate, a first semiconductor chip on the first package substrate, an interposer on the first semiconductor chip, a support substrate on the first package substrate and apart from a sidewall of the first semiconductor chip, a conductive filler on the support substrate, a connection bump between the support substrate and the interposer and electrically connecting the conductive filler to the interposer, and a first molding layer surrounding the sidewall of the first semiconductor chip and a sidewall of the connection bump.

In some implementations, a semiconductor package includes a first package substrate, a first semiconductor chip on the first package substrate, an interposer on the first semiconductor chip, a heat transfer material layer filling at least a portion of a gap between a bottom surface of the interposer and a top surface of the first semiconductor chip, a support substrate on the first package substrate and apart from a sidewall of the first semiconductor chip, a conductive filler on the support substrate, a connection bump between the support substrate and the interposer and surrounding a sidewall and a top surface of the conductive filler, and a first molding layer surrounding the sidewall of the first semiconductor chip and a sidewall of the connection bump.

In some implementations, a semiconductor package includes a first package substrate, a first semiconductor chip on the first package substrate, an interposer on the first semiconductor chip, a support substrate on the first package substrate and apart from a sidewall of the first semiconductor chip, a conductive filler on the support substrate, a connection bump between the support substrate and the interposer, the connection bump surrounding a sidewall and a top surface of the conductive filler and electrically connecting the conductive filler to the interposer, a first molding layer surrounding the sidewall of the first semiconductor chip and a sidewall of the connection bump and being in contact with at least a portion of the sidewall of the connection bump, a second package substrate on the interposer, a second semiconductor chip on the second package substrate, and a second molding layer surrounding a sidewall of the second semiconductor chip.

### BRIEF DESCRIPTION OF THE DRAWINGS

Implementations will be more clearly understood from the following detailed description taken in conjunction with the accompanying drawings.

FIG. 1A is a cross-sectional view of an example of a semiconductor package.

FIG. 1B is an example enlarged view of a region EX shown in FIG. 1A.

FIG. 2 is an enlarged view of a portion of an example of a semiconductor package.

FIG. 3 is a cross-sectional view of another example of a semiconductor package.

FIG. 4 is a cross-sectional view of another example of a semiconductor package.

FIG. 5 is a cross-sectional view of another example of a semiconductor package.

FIG. 6 is a cross-sectional view of another example of a semiconductor package.

FIGS. 7 to 12B are cross-sectional views showing stages of an example of a method of manufacturing a semiconductor package.

### DETAILED DESCRIPTION

Hereinafter, implementations will be described with reference to the accompanying drawings. In the drawings, like numerals denote like elements and redundant descriptions thereof will be omitted.

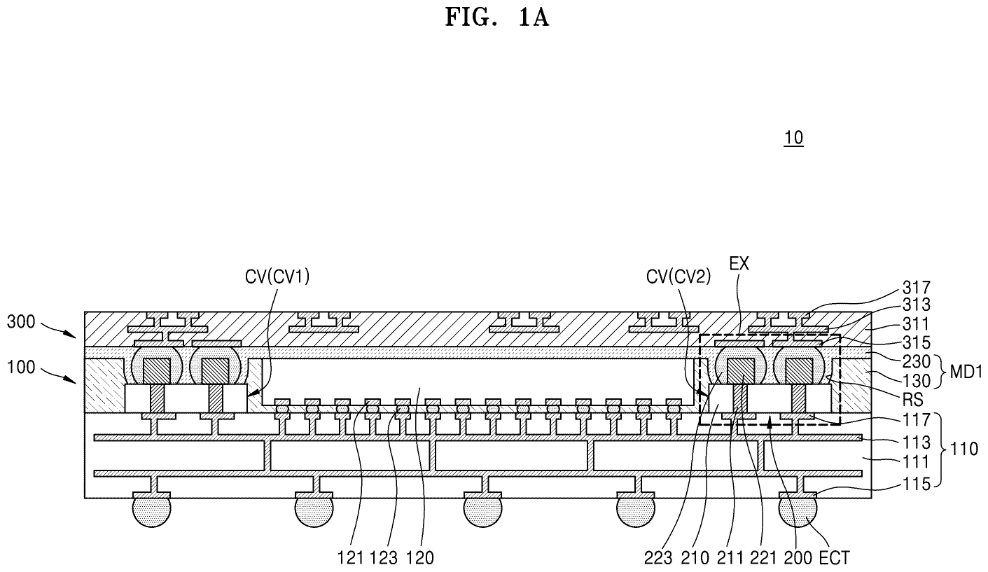

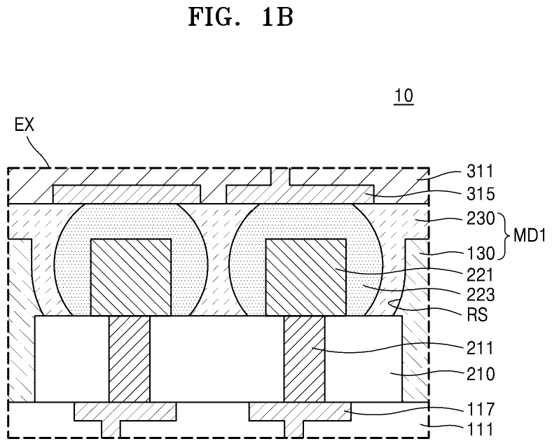

FIG. 1A is a cross-sectional view of an example of a semiconductor package 10. FIG. 1B is an example enlarged view of a region EX shown in FIG. 1A.

Referring to FIGS. 1A and 1B, the semiconductor package 10 may include a first package 100, a support substrate 200 and an interposer 300, which are on the first package 100, and a conductive via 211, a conductive filler 221, and a connection bump 223, which electrically connect the first package 100 to the interposer 300.

The first package 100 may include a first package substrate 110, a first semiconductor chip 120, and a first molding layer MD1. For example, the first package 100 may correspond to a flip-chip package, in which the first semiconductor chip 120 is mounted on the first package substrate 110 in a face-down manner. In this case, a chip connection terminal 123 may be between a first chip pad 121 of the first semiconductor chip 120 and an upper pad 117 of the first package substrate 110 and may electrically and/or physically connect the first chip pad 121 of the first semiconductor chip 120 to the upper pad 117 of the first package substrate 110.

For example, the first package substrate 110 may correspond to a printed circuit board (PCB). The first package substrate 110 may include a substrate base 111 including at least one material selected from the group consisting of phenol resin, epoxy resin, and polyimide. The first package substrate 110 may include the upper pad 117 and a lower pad 115, which are respectively on the top and bottom surfaces of the substrate base 111. An internal wiring 113 may be formed in the substrate base 111 to electrically connect the upper pad 117 to the lower pad 115.

For example, the upper pad 117 and the lower pad 115 may include, but not limited to, metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), or an alloy thereof.

The upper pad 117 may function as a pad, to which the conductive via 211 or the chip connection terminal 123 is attached. The lower pad 115 may function as a pad to which an external connection terminal ECT is attached. For example, the external connection terminal ECT may include a solder ball or a bump. The external connection terminal ECT may electrically connect the semiconductor package 10 to an external device.

The first semiconductor chip 120 may be mounted on the first package substrate 110. The first semiconductor chip 120 may include a semiconductor substrate, which has an active surface and an inactive surface opposite to the active surface, and a semiconductor individual device layer on the active surface of the semiconductor substrate. The first semiconductor chip 120 may include a bottom surface and a top surface opposite to the bottom surface. The first chip pad 121 may be on the bottom surface of the first semiconductor chip 120. The first chip pad 121 of the first semiconductor chip 120 may be electrically connected to the semiconductor individual device layer through a wiring structure.

The first semiconductor chip 120 may correspond to a memory chip and include a volatile memory chip and/or a non-volatile memory chip. For example, the volatile memory chip may include dynamic random access memory (DRAM), static RAM (SRAM), thyristor RAM (TRAM), zero-capacitor RAM (ZRAM), or twin transistor RAM (TTRAM). For example, the non-volatile memory chip may include flash memory, electrically erasable and programmable read-only memory (EEPROM), phase-change RAM (PRAM), magnetic RAM (MRAM), spin-transfer torque MRAM (STT-MRAM), ferroelectric RAM (FRAM), resistive RAM (RRAM), nanotube RRAM, polymer RAM, or insulator resistance change memory.

The first semiconductor chip 120 may correspond to a non-memory chip. For example, the first semiconductor chip 120 may correspond to a logic chip and may be implemented as, but not limited to, an artificial intelligence (AI) semiconductor, a microprocessor, a graphics processor, a signal processor, a network processor, a chipset, an audio codec, a video codec, an application processor, or a system-on-chip.

The first semiconductor chip 120 may be mounted on the first package substrate 110 such that a surface of the first semiconductor chip 120, on which the first chip pad 121 is arranged, faces upwards. The first chip pad 121 of the first semiconductor chip 120 may be used as a terminal for transmission of an input/output data signal of the first semiconductor chip 120 or a terminal for power and/or ground of the first semiconductor chip 120.

The interposer 300 may be above the first semiconductor chip 120. At this time, the bottom surface of the interposer 300 may be apart from the top surface of the first semiconductor chip 120. The interposer 300 may include an interposer substrate base 311 including at least one material selected from the group consisting of phenol resin, epoxy resin, and polyimide. The interposer 300 may include an interposer upper pad 317 and an interposer lower pad 315, which are respectively on the top and bottom surfaces of the interposer substrate base 311. An interposer internal wiring 313 may be formed in the interposer substrate base 311 to electrically connect the interposer upper pad 317 to the interposer lower pad 315.

For example, the interposer upper pad 317 and the interposer lower pad 315 may include, but not limited to, metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), or an alloy thereof.

The support substrate 200 may be on the first package substrate 110 and apart from a sidewall of the first semiconductor chip 120. The support substrate 200 may include a cavity CV. The cavity CV of the support substrate 200 may include a first portion and a second portion, which is apart from the first portion with the first semiconductor chip 120 between the first portion and the second portion of the cavity CV, and may be defined by a space between the first portion and the second portion. The first semiconductor chip 120 may be in the cavity CV of the support substrate 200. In detail, the first semiconductor chip 120 may be between a first sidewall CV1 of the cavity CV and a second sidewall CV2 facing the first sidewall CV1. Although not shown, in a layout, the support substrate 200 may extend to surround the first semiconductor chip 120.

The support substrate 200 may include a first sidewall facing the first semiconductor chip 120 and a second sidewall facing the first sidewall. The first sidewall of the support substrate 200 may be apart from the sidewall of the first semiconductor chip 120 in a horizontal direction. The second sidewall of the support substrate 200 is illustrated to form a different plane in the vertical direction than a sidewall of the first package substrate 110 but may be aligned and coplanar with the sidewall of the first package substrate 110 in the vertical direction. The first sidewall of the support substrate 200 may be surrounded by the first molding layer MD1. The second sidewall of the support substrate 200 may be surrounded by the first molding layer MD1 when the second sidewall of the support substrate 200 forms a different plane in the vertical direction than the sidewall of the first package substrate 110.

The support substrate 200 may support the conductive filler 221 and the connection bump 223, which are described below. In some implementations, the support substrate 200 may correspond to a PCB. In some implementations, the support substrate 200 may include a support substrate base 210 and the conductive via 211, which passes through the support substrate base 210 in the vertical direction.

The support substrate base 210 may include an insulating material. For example, the support substrate base 210 may include silicon, glass, ceramic, plastic, or a polymer. The polymer may include at least one material selected from the group consisting of phenol resin, epoxy resin, and polyimide. In some implementations, the support substrate base 210 may include a plurality of layers. For example, the support substrate base 210 may include a core layer and a protective layer on the core layer.

The conductive via 211 may include a metal layer, with which the inside of a via hole passing through the support substrate base 210 in the vertical direction is coated. The conductive via 211 may be provided as a solder ball and may include solder resist ink filling the via hole.

The conductive filler 221 electrically connected to the conductive via 211 may be on the support substrate 200. The bottom surface of the conductive filler 221 may be surrounded by the support substrate 200 and the sidewall and top surface of the conductive filler 221 may be surrounded by the connection bump 223. The conductive filler 221 may have a cylindrical shape but is not limited thereto and may be formed in various shapes. A plurality of conductive fillers 221 may be provided on the support substrate 200 and may include two conductive fillers 221, as shown in FIG. 1A. However, implementations are not limited thereto, and the plurality of conductive fillers 221 may include at least three conductive fillers 221.

The conductive filler 221 may include at least one selected from the group consisting of aluminum (Al), copper (Cu), nickel (Ni), tungsten (W), platinum (Pt), and gold (Au). For example, the conductive filler 221 may include copper (Cu) or a combination of copper (Cu) and nickel (Ni).

The connection bump 223 may surround the sidewall and top surface of the conductive filler 221. The connection bump 223 may be between the support substrate 200 and the interposer 300. The connection bump 223 may include a first connection portion between the top surface of the conductive filler 221 and the interposer lower pad 315 of the interposer 300 and a second connection portion covering the sidewall of the conductive filler 221. The conductive filler 221 may be apart from the interposer lower pad 315 with the first connection portion of the connection bump 223 between the conductive filler 221 and the interposer lower pad 315. The conductive filler 221 may also be apart from the first semiconductor chip 120 with the second connection portion of the connection bump 223 between the conductive filler 221 and the first semiconductor chip 120.

The connection bump 223 may be in contact with and electrically connected to the interposer lower pad 315. The connection bump 223 may be electrically connected to the conductive via 211 through the conductive filler 221. The conductive filler 221 may be electrically connected to the interposer lower pad 315 through the connection bump 223, which is in contact with the interposer lower pad 315.

The vertical height of the connection bump 223 may be about 50 micrometers to about 70 micrometers The vertical height from the top surface of the conductive filler 221 to the top surface of the connection bump 223 may be about 20 micrometers to about 40 micrometers.

The sidewall of the connection bump 223 may be surrounded by the first molding layer MD1. In some implementations, the sidewall of the connection bump 223 may be surrounded by an upper molding layer 230. In some implementations, an upper portion of the sidewall of the connection bump 223 may be covered with the upper molding layer 230 and a lower portion of the sidewall of the connection bump 223 may be covered with a lower molding layer 130.

The connection bump 223 may include a conductive material, e.g., solder. The connection bump 223 may include a different material than the conductive filler 221. For example, the connection bump 223 may include a solder ball.

Compared to the sidewall of the conductive filler 221, the sidewall of the connection bump 223 may have a relatively curved shape. In detail, the sidewall of the conductive filler 221 may extend in a straight line from the top surface of the support substrate 200 in the vertical direction, and the sidewall of the connection bump 223 may bulge toward the sidewall of the first semiconductor chip 120. The horizontal width of the conductive filler 221 may be substantially uniform throughout the conductive filler 221. The horizontal width of the connection bump 223 may be maximum at the central portion of the connection bump 223 and may decrease toward the top or bottom of the connection bump 223. The top and bottom surface of the connection bump 223 may be flat unlike the sidewall of the connection bump 223. The top surface of the connection bump 223 may be coplanar with the bottom surface of the interposer lower pad 315 and the bottom surface of the connection bump 223 may be coplanar with the top surface of the support substrate 200.

The upper pad 117 of the first package substrate 110 may be electrically connected to the interposer lower pad 315 of the interposer 300. In detail, the upper pad 117 of the first package substrate 110 may be electrically connected to the interposer lower pad 315 of the interposer 300 through the conductive via 211, the conductive filler 221, and the connection bump 223. The conductive via 211 may be electrically connected to the interposer lower pad 315 through the conductive filler 221 and the connection bump 223.

The first molding layer MD1 may be on the first package substrate 110. The first molding layer MD1 may be between the first package substrate 110 and the interposer 300 and may surround the sidewall of the first semiconductor chip 120, the sidewall of the support substrate 200, and the sidewall of the connection bump 223. The first molding layer MD1 may protect the first semiconductor chip 120 from an external environment. In some implementations, the first molding layer MD1 may include the lower molding layer 130 and the upper molding layer 230 on the lower molding layer 130.

The lower molding layer 130 may be on the first package substrate 110. The lower molding layer 130 may surround the sidewall of the first semiconductor chip 120. In some implementations, the lower molding layer 130 may cover the sidewall of the first semiconductor chip 120 but may not cover the top surface of the first semiconductor chip 120. The lower molding layer 130 may cover at least a portion of the sidewall of the support substrate 200. Although it is illustrated that the lower molding layer 130 does not cover the sidewall of the connection bump 223, implementations are not limited thereto. The lower molding layer 130 may cover a portion of the sidewall of the connection bump 223.

The lower molding layer 130 may fill the gap between the first semiconductor chip 120 and the first package substrate 110 and surround the chip connection terminal 123 between the first semiconductor chip 120 and the first package substrate 110. Although not shown, the semiconductor package 10 may further include an underfill, which fills the gap between the first semiconductor chip 120 and the first package substrate 110 and surrounds the chip connection terminal 123 between the first semiconductor chip 120 and the first package substrate 110. The underfill may be formed by a capillary underfill process using underfill resin.

The lower molding layer 130 may be formed by implanting an appropriate amount of molding material around the first semiconductor chip 120 and hardening the molding material. In some implementations, the lower molding layer 130 may be formed through compression molding. In some implementations, the molding material for forming the lower molding layer 130 may include epoxy-group molding resin or polyimide-group molding resin. For example, the lower molding layer 130 may include an epoxy molding compound (EMC) and may further include a filler or a hardener.

The lower molding layer 130 may include a recess RS. The recess RS may include a space defined by the inner wall of the lower molding layer 130 and the top surface of the support substrate 200. The recess RS may be configured to expose the conductive filler 221 from the lower molding layer 130 to the outside. The conductive filler 221 and the connection bump 223 surrounding the sidewall and top surface of the conductive filler 221 may be arranged in the recess RS.

In some implementations, the sidewall of the recess RS may be apart from the sidewall of the conductive filler 221 and may be between the sidewall of the first semiconductor chip 120 and the sidewall of the conductive filler 221. Although it is illustrated that the connection bump 223 is apart from the sidewall of the recess RS, implementations are not limited thereto. The connection bump 223 may be in contact with at least a portion of the sidewall of the recess RS.

In some implementations, it is illustrated that a portion of the sidewall of the recess RS is curved, but the shape of the sidewall of the recess RS is not limited thereto. For example, the sidewall of the recess RS may have a straight-line structure. In some implementations, the horizontal width of the recess RS may decrease downwards.

In some implementations, the top surface of the first semiconductor chip 120, the top surface of the lower molding layer 130, or the top surface of the conductive filler 221 may be planarized. For example, the top surface of the first semiconductor chip 120, the top surface of the lower molding layer 130, or the top surface of the conductive filler 221 may be planarized through strip grinding. Accordingly, the surface roughness of the top surface of the first semiconductor chip 120 may be greater than that of the sidewall or bottom surface of the first semiconductor chip 120, the surface roughness of the top surface of the lower molding layer 130 may be greater than that of the sidewall of bottom surface of the lower molding layer 130, and the surface roughness of the top surface of the conductive filler 221 may be greater than that of the sidewall or bottom surface of the conductive filler 221.

Because the top surface of each of the first semiconductor chip 120, the lower molding layer 130, and the conductive filler 221 may be planarized, the surface roughness of the top surface of each of the first semiconductor chip 120, the lower molding layer 130, and the conductive filler 221 may be greater than that of the other surface of each of the first semiconductor chip 120, the lower molding layer 130, and the conductive filler 221. Accordingly, an adhesive strength between each of the first semiconductor chip 120, the lower molding layer 130, and the conductive filler 221 and an element disposed on each of the first semiconductor chip 120, the lower molding layer 130, and the conductive filler 221 may increase.

In some implementations, a vertical height of the first semiconductor chip 120 may be about 30 micrometers to about 50 micrometers, a vertical height of the conductive filler 221 may be about 20 micrometers to about 40 micrometers, and a maximum vertical height of the lower molding layer 130 may be about 60 micrometers to about 80 micrometers.

The respective top surfaces of the first semiconductor chip 120, the lower molding layer 130, and the conductive filler 221 may be substantially coplanar with one another. In other words, the respective top surfaces of the first semiconductor chip 120, the lower molding layer 130, and the conductive filler 221 may be substantially at the same level. In detail, the level of the top surface of each of the lower molding layer 130 and the conductive filler 221 may be within 20 micrometers in the vertical direction from the level of the top surface of the first semiconductor chip 120.

The upper molding layer 230 may be on the lower molding layer 130. The upper molding layer 230 may fill at least a portion of the gap between the bottom surface of the interposer 300 and the top surface of the lower molding layer 130 and at least a portion of the gap between the bottom surface of the interposer 300 and the top surface of the first semiconductor chip 120. The upper molding layer 230 may cover the top surface of the first semiconductor chip 120 and the top surface of the lower molding layer 130 and may extend to cover the inner wall of the lower molding layer 130. The upper molding layer 230 may fill at least a portion of the gap between the inner wall of the lower molding layer 130 and the sidewall of the connection bump 223. When there are a plurality of connection bumps 223, the upper molding layer 230 may fill at least a portion of the gap between adjacent connection bumps 223.

The upper molding layer 230 may fill at least a portion of the recess RS and at least a portion of the gap between the support substrate 200 and the interposer 300. In detail, the upper molding layer 230 may fill the portion of the recess RS, which is not filled with the conductive filler 221 and the connection bump 223. For example, lower molding layer 130 defining the recess RS including a first portion and a second portion, the conductive filler 221 and the connection bump 223 are filled with the first portion of the recess RS, and the upper molding layer 230 is configured to fill the second portion of the recess RS.

At least a portion of the sidewall of the support substrate 200 may be covered with the lower molding layer 130, and the other portion of the sidewall of the support substrate 200 may be covered with the upper molding layer 230. Accordingly, the sidewall of the support substrate 200 may be surrounded by the first molding layer MD1. At least a portion of the sidewall of the connection bump 223 may be covered with the upper molding layer 230 and the other portion of the sidewall of the connection bump 223 may be covered with the lower molding layer 130. Accordingly, the sidewall of the connection bump 223 may be surrounded by the first molding layer MD1.

In some implementations, the upper molding layer 230 may be formed by implanting an appropriate amount of molding material between the first package 100 and the interposer 300 and hardening the molding material. In some implementations, the upper molding layer 230 may be formed through transfer molding. In some implementations, the molding material for forming the upper molding layer 230 may include epoxy-group molding resin or polyimide-group molding resin. For example, the upper molding layer 230 may include an EMC and may further include a filler or a hardener.

In some implementations, the upper molding layer 230 may include a different material than the lower molding layer 130. In some implementations, the upper molding layer 230 may have a different chemical composition ratio than the lower molding layer 130. For example, the ratio of EMC, filler, and hardener in the lower molding layer 130 may be different from the ratio of EMC, filler, and hardener in the upper molding layer 230.

There may be an interface between the upper molding layer 230 and the lower molding layer 130. In detail, a cut surface of the filler of the lower molding layer 130 may be observed on the top surface of the lower molding layer 130.

In some implementations, the maximum vertical height of the first molding layer MD1 may be about 90 micrometers to about 110 micrometers. The maximum vertical height of the lower molding layer 130 may be about 60 micrometers to about 80 micrometers, and the maximum vertical height of the upper molding layer 230 may be about 30 micrometers to about 70 micrometers.

According to some implementations, because the sidewall and top surface of the conductive filler 221 are surrounded by the connection bump 223, detachment between the conductive filler 221 and the connection bump 223 may be prevented, and therefore, a semiconductor package having improved reliability may be provided.

In addition, because the sidewall of the connection bump 223 is surrounded by the first molding layer MD1, detachment between the connection bump 223 and the interposer lower pad 315 may be prevented, and therefore, a semiconductor package having improved reliability may be provided.

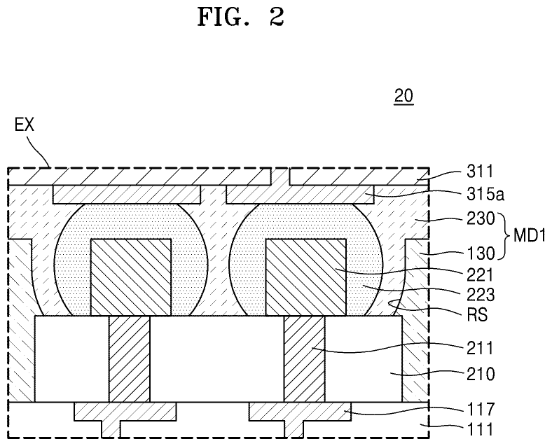

FIG. 2 is an enlarged view of a portion of an example of a semiconductor package. FIG. 2 shows a portion corresponding to the region EX in FIG. 1A. A semiconductor package 20 of FIG. 2 may be substantially the same as or similar to the semiconductor package 10 described with reference to FIGS. 1A and 1B, except for an interposer lower pad 315a. The semiconductor package 20 is described below focusing on the differences from the semiconductor package 10 of FIGS. 1A and 1B.

Referring to FIG. 2, the interposer 300 (in FIG. 1A) may include the interposer lower pad 315a, which is arranged on the bottom surface of the interposer substrate 310 (in FIG. 1A) to be connected to the connection bump 223. At least a portion of the interposer lower pad 315a may protrude from the bottom surface of the interposer 300. The entirety or a portion of the interposer lower pad 315a may protrude from the bottom surface of the interposer 300.

As the interposer lower pad 315a protrudes from the interposer substrate base 311, the sidewall of the interposer lower pad 315a may be covered with the upper molding layer 230.

Because the interposer lower pad 315a protrudes from the bottom surface of the interposer 300, a material of the connection bump 223 may easily adhere to the interposer lower pad 315a when the connection bump 223 is formed through a reflow process.

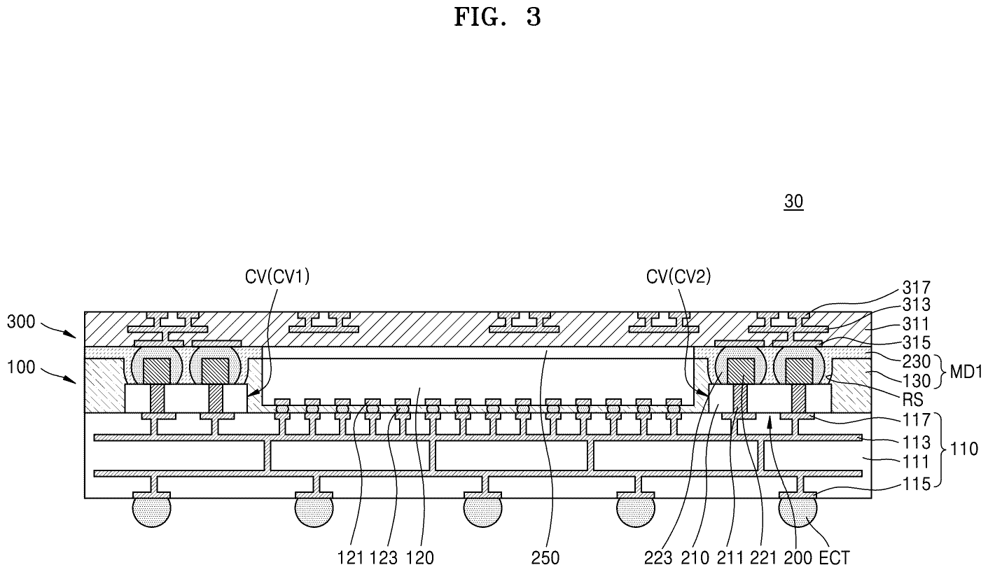

FIG. 3 is a cross-sectional view of another example of a semiconductor package 30. The semiconductor package 30 of FIG. 3 may be substantially the same as or similar to the semiconductor package 10 described with reference to FIGS. 1A and 1B, except that the semiconductor package 30 may further include a heat transfer material layer 250. The semiconductor package 30 is described below focusing on the differences from the semiconductor package 10 of FIGS. 1A and 1B.

Referring to FIG. 3, the semiconductor package 30 may include the first package 100 and the interposer 300 on the first package 100.

The first package 100 may include the first package substrate 110, the first semiconductor chip 120, the first molding layer MD1, the support substrate 200, the conductive filler 221, the connection bump 223, and the heat transfer material layer 250.

The first molding layer MD1 may include the lower molding layer 130 and the upper molding layer 230. The upper molding layer 230 may be on the lower molding layer 130. In detail, the upper molding layer 230 may fill at least a portion of the gap between the bottom surface of the interposer 300 and the top surface of the lower molding layer 130. The upper molding layer 230 may cover the top surface of the lower molding layer 130 and may extend to cover the inner wall of the lower molding layer 130. The upper molding layer 230 may fill at least a portion of the gap between the inner wall of the lower molding layer 130 and the sidewall of the connection bump 223. When there are a plurality of connection bumps 223, the upper molding layer 230 may fill at least a portion of the gap between adjacent connection bumps 223.

The upper molding layer 230 may fill at least a portion of the recess RS and at least a portion of the gap between the support substrate 200 and the interposer 300. In detail, the upper molding layer 230 may fill the portion of the recess RS, which is not filled with the conductive filler 221 and the connection bump 223.

At least a portion of the sidewall of the support substrate 200 may be covered with the lower molding layer 130, and the other portion of the sidewall of the support substrate 200 may be covered with the upper molding layer 230. Accordingly, the sidewall of the support substrate 200 may be surrounded by the first molding layer MD1. At least a portion of the sidewall of the connection bump 223 may be covered with the upper molding layer 230 and the other portion of the sidewall of the connection bump 223 may be covered with the lower molding layer 130. Accordingly, the sidewall of the connection bump 223 may be surrounded by the first molding layer MD1.

The upper molding layer 230 may fill at least a portion of the gap between the first package 100 and the interposer 300. In detail, the heat transfer material layer 250 may fill at least a portion of the gap between the bottom surface of the interposer 300 and the top surface of the first semiconductor chip 120. The other portion of the gap between the bottom surface of the interposer 300 and the top surface of the first semiconductor chip 120, which is not filled with the heat transfer material layer 250, may be filled with the upper molding layer 230. The heat transfer material layer 250 may cover at least a portion of the top surface of the first semiconductor chip 120. The other portion of the first semiconductor chip 120, which is not covered with the heat transfer material layer 250, may be covered with the upper molding layer 230.

The top surface of the heat transfer material layer 250 may be surrounded by the interposer 300, the bottom surface of the heat transfer material layer 250 may be surrounded by the first semiconductor chip 120 or the lower molding layer 130, and the sidewall of the heat transfer material layer 250 may be surrounded by the upper molding layer 230. The sidewall of the heat transfer material layer 250 may be apart from the sidewall of the connection bump 223, and the upper molding layer 230 may fill at least a portion of the gap between the sidewall of the heat transfer material layer 250 and the sidewall of the connection bump 223.

Because the top surface of each of the first semiconductor chip 120, the lower molding layer 130, and the conductive filler 221 may be planarized, the surface roughness of the top surface of each of the first semiconductor chip 120, the lower molding layer 130, and the conductive filler 221 may be greater than that of the other surface of each of the first semiconductor chip 120, the lower molding layer 130, and the conductive filler 221. Accordingly, an adhesive strength between the first semiconductor chip 120 and the heat transfer material layer 250 disposed on the first semiconductor chip 120 may increase.

The sidewall of the heat transfer material layer 250 is illustrated to be aligned and coplanar with the sidewall of the first semiconductor chip 120 in the vertical direction but may form a different plane than the sidewall of the first semiconductor chip 120. Although it is illustrated that the horizontal width of the heat transfer material layer 250 is the same as that of the first semiconductor chip 120, implementations are not limited thereto. For example, the horizontal width of the heat transfer material layer 250 may be greater than that of the first semiconductor chip 120.

The heat transfer material layer 250 may include a polymer material having a high thermal conductivity. For example, the heat transfer material layer 250 may include, but not limited to, a thermal conductive adhesive tape, thermal conductive grease, a thermal conductive interface pad, a thermal conductive adhesive, or a combination thereof.

The bottom surface of the heat transfer material layer 250 may be substantially coplanar with the top surface of the conductive filler 221 or the top surface of the lower molding layer 130. A vertical height of the heat transfer material layer 250 may be substantially equal to the distance between the top surface of the first semiconductor chip 120 and the bottom surface of the interposer 300 and equal to a vertical height from the top surface of the lower molding layer 130 to the top surface of the upper molding layer 230. The vertical height of the heat transfer material layer 250 may also be substantially equal to a vertical height of the first connection portion of the connection bump 223, which is between the top surface of the conductive filler 221 and the interposer lower pad 315 of the interposer 300. In some implementations, the vertical height of the heat transfer material layer 250 may be about 20 micrometers to about 40 micrometers.

According to some implementations, the performance of the first semiconductor chip 120 may be prevented from degrading due to the heat transfer material layer 250, and accordingly, a semiconductor package having an improved heat dissipation characteristic may be provided.

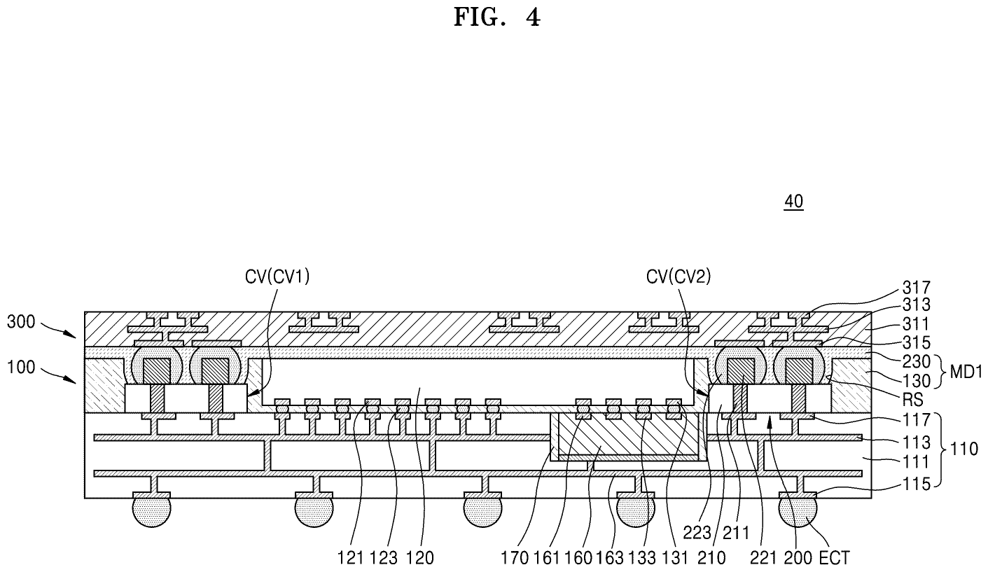

FIG. 4 is a cross-sectional view of another example of a semiconductor package 40.

The semiconductor package 40 of FIG. 4 may be substantially the same as or similar to the semiconductor package 10 described with reference to FIGS. 1A and 1B, except that the semiconductor package 30 may further include a buried semiconductor device 160. The semiconductor package 40 is described below focusing on the differences from the semiconductor package 10 of FIGS. 1A and 1B.

Referring to FIG. 4, the semiconductor package 40 may include the first package 100, the interposer 300 on the first package 100, the conductive via 211, the conductive filler 221, and the connection bump 223, which electrically connect the first package 100 to the interposer 300, and the upper molding layer 230 between the first package 100 and the interposer 300 and may further include the buried semiconductor device 160 embedded in the first package substrate 110, wherein the conductive via 211 passes through the support substrate 200. For example, the buried semiconductor device 160 may be accommodated in a recess of the first package substrate 110. The buried semiconductor device 160 may be attached to the bottom of the recess of the first package substrate 110 via an adhesive film 163. A buried insulating layer 170 may be provided in the recess of the first package substrate 110 and may cover at least a portion of the buried semiconductor device 160.

The buried semiconductor device 160 may be electrically connected to the first semiconductor chip 120. For example, the buried semiconductor device 160 may be accommodated in the recess of the first package substrate 110 such that a surface of the buried semiconductor device 160 having thereon a pad 161 faces the first semiconductor chip 120. The buried semiconductor device 160 may be electrically connected to first semiconductor chip 120 through a connection terminal 133 between the pad 161 of buried semiconductor device 160 and a first chip pad 131 of the first semiconductor chip 120.

In some implementations, the buried semiconductor device 160 may correspond to a memory chip, a logic chip, an active device, or a passive device. In some implementations, the buried semiconductor device 160 may correspond to a semiconductor chip that is of different type than the first semiconductor chip 120. For example, when the first semiconductor chip 120 corresponds to a logic chip, such as an AP, the buried semiconductor device 160 may correspond to a memory chip.

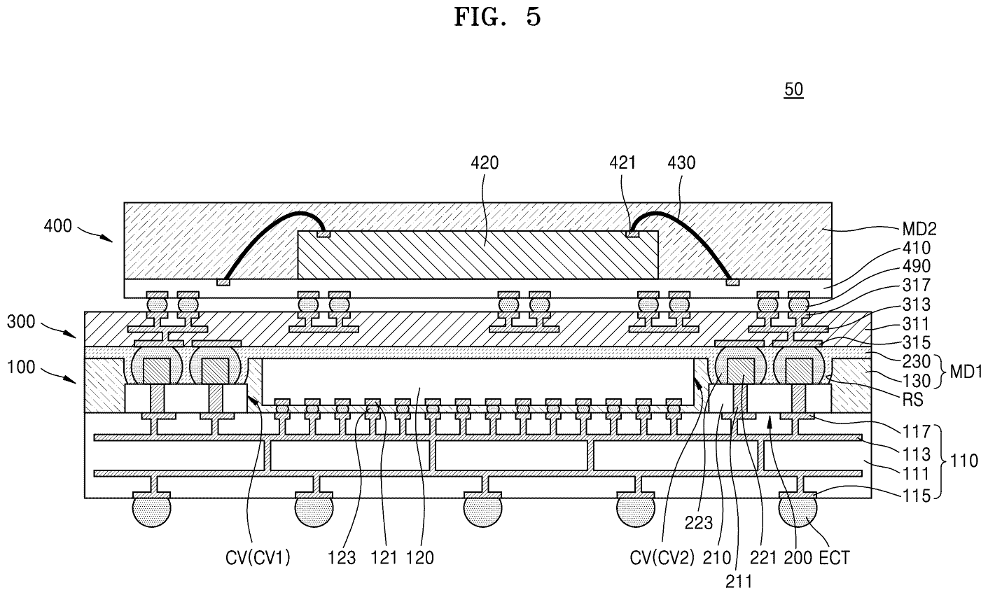

FIG. 5 is a cross-sectional view of another example of a semiconductor package 50.

The semiconductor package 50 of FIG. 5 may be substantially the same as or similar to the semiconductor package 10 described with reference to FIGS. 1A and 1B, except that the semiconductor package 50 may further include a second package 400. The semiconductor package 50 is described below focusing on the differences from the semiconductor package 10 of FIGS. 1A and 1B.

Referring to FIG. 5, the semiconductor package 50 may include the first package 100, the interposer 300 stacked on the first package 100, and the second package 400 stacked on the interposer 300. The semiconductor package 50 may be of a package-on-package (POP) type, in which the first package 100 and the second package 400 may respectively form a lower package and an upper package.

The second package 400 may include a second package substrate 410, a second semiconductor chip 420 on the second package substrate 410, and a second molding layer MD2 surrounding the top surface of the second package substrate 410 and the sidewall of the second semiconductor chip 420.

For example, the second package substrate 410 may correspond to a PCB. The second package substrate 410 may include an upper pad and a lower pad, which are respectively on the top and bottom surface of the second package substrate 410. The second package substrate 410 may be electrically connected to the interposer 300 through a connection terminal 490 between the lower pad of the second package substrate 410 and the interposer upper pad 317 of the interposer 300.

For example, the second semiconductor chip 420 may be mounted on the second package substrate 410 in a face-up manner. In this case, a second chip pad 421 of the second semiconductor chip 420 may be electrically connected to the upper pad of the second package substrate 410 through a conductive wire 430. The second semiconductor chip 420 may be electrically connected to the first semiconductor chip 120 or the external connection terminal ECT through the interposer 300.

In some implementations, the second semiconductor chip 420 may be of different type than the first semiconductor chip 120. For example, when the first semiconductor chip 120 corresponds to a logic chip, the second semiconductor chip 420 may correspond to a memory chip. In some implementations, the semiconductor package 50 may correspond to a system-in-package, in which different kinds of semiconductor chips are electrically connected to each other and operate as a single system. In some implementations, the first semiconductor chip 120 and the second semiconductor chip 420 may be of the same types.

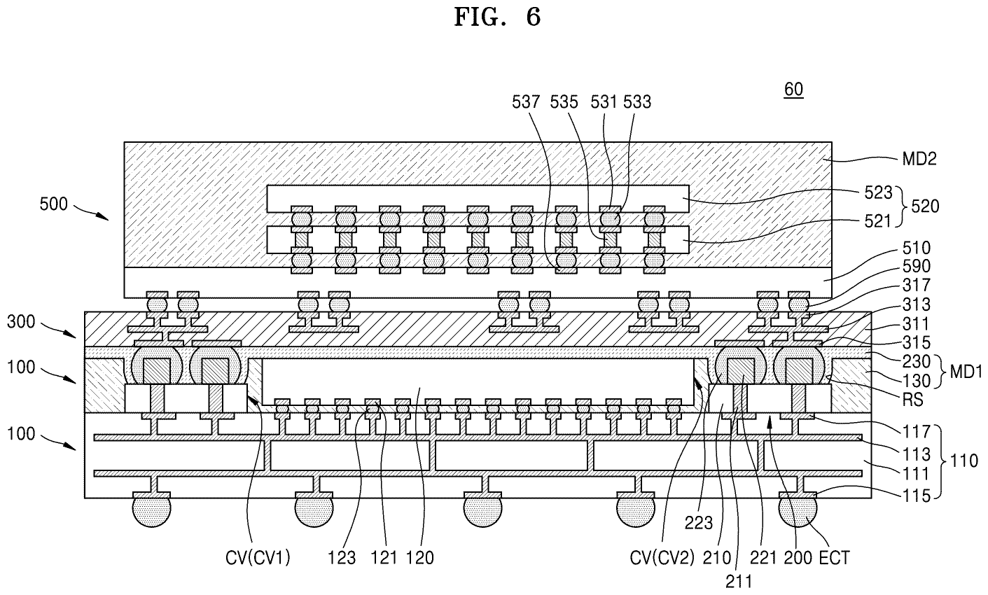

FIG. 6 is a cross-sectional view of another example of a semiconductor package 60.

The semiconductor package 60 of FIG. 6 may be substantially the same as or similar to the semiconductor package 10 described with reference to FIGS. 1A and 1B, except that the semiconductor package 60 may further include a second package 500. The semiconductor package 60 is described below focusing on the differences from the semiconductor package 10 of FIGS. 1A and 1B.

Referring to FIG. 6, the semiconductor package 60 may include the first package 100, the interposer 300 stacked on the first package 100, and the second package 500 stacked on the interposer 300. The semiconductor package 60 may be of a PoP type, in which the first package 100 and the second package 500 may respectively form a lower package and an upper package.

The second package 500 may include a second package substrate 510, at least two second semiconductor chips 520 on the second package substrate 510, and the second molding layer MD2 surrounding the top surface of the second package substrate 510 and the sidewalls of the second semiconductor chips 520. The second semiconductor chips 520 may be mounted on the second package substrate 510 in a flip-chip manner. The second semiconductor chips 520 may be stacked such that an active surface of each of the second semiconductor chips 520 faces the second package substrate 510. Herein, the second semiconductor chips 520 may include a lower second semiconductor chip 521, which is close to the second package substrate 510, among the second semiconductor chips 520 and an upper second semiconductor chip 523, which is close to the lower second semiconductor chip 521, among the second semiconductor chips 520.

A plurality of chip pads 531 may be at the top and/or bottom of each of the second semiconductor chips 520. The chip pads 531 at the bottom of the lower second semiconductor chip 521 may be electrically and respectively connected to bonding pads 537 at the top of the second package substrate 510 respectively through chip connection bumps 533.

The chip pads 531 at the bottom of the upper second semiconductor chip 523 may be electrically and respectively connected to the chip pads 531 at the top of the lower second semiconductor chip 521 respectively through chip connection bumps 533. The chip pads 531 at the bottom of the upper second semiconductor chip 523 may be electrically and respectively connected to the chip pads 531 at the bottom of the lower second semiconductor chip 521 respectively via through electrodes 535.

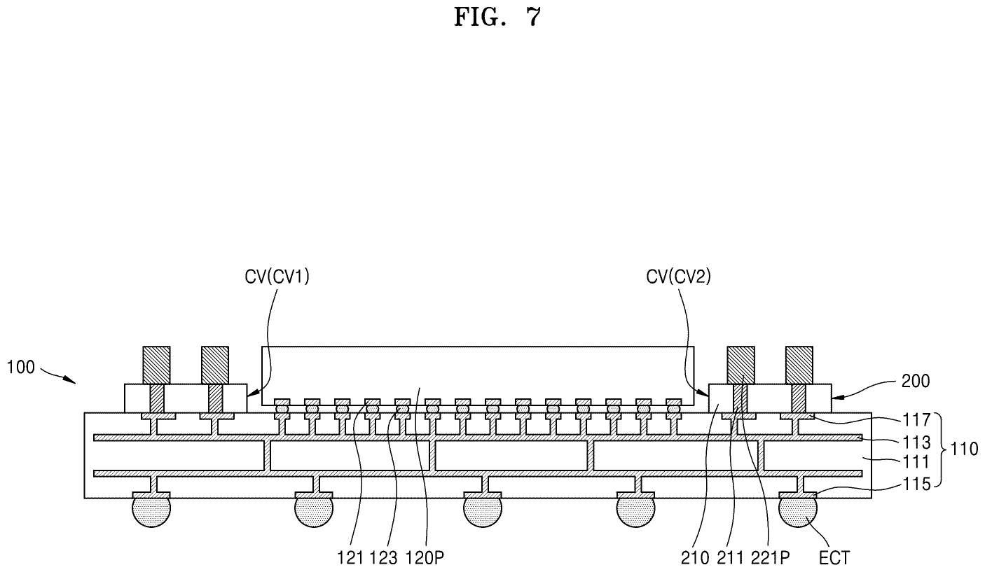

FIGS. 7 to 12B are cross-sectional views of stages in another example of a method of manufacturing a semiconductor package. Hereinafter, a method of manufacturing the semiconductor package 10 of FIG. 1A is described with reference to FIGS. 7 to 10 and FIGS. 11A and 12A, and a method of manufacturing the semiconductor package 30 of FIG. 3 is described with reference to FIGS. 7 to 10 and FIGS. 11B and 12B.

Referring to FIG. 7, the support substrate 200 including the cavity CV may be formed on the first package substrate 110. The cavity CV of the support substrate 200 may be configured to connect an upper pad 117 of the first package substrate 110 to a first chip pad 121 of a preliminary first semiconductor chip 120P. The upper pad 117 of the first package substrate 110, which is to be connected to the first chip pad 121 of a preliminary first semiconductor chip 120P, may be exposed by the cavity CV of the support substrate 200.

In detail, after the support substrate base 210 is attached to the first package substrate 110, a through hole may be etched to expose the upper pad 117 and a conductive via 211 may be formed by filling the through hole with a conductive material, so that the support substrate 200 may be formed. The conductive via 211 may be in contact with the top surface of the upper pad 117.

Thereafter, a preliminary conductive filler 221P may be formed on the support substrate 200. The preliminary conductive filler 221P may include at least one selected from the group consisting of aluminum (Al), copper (Cu), nickel (Ni), tungsten (W), platinum (Pt), and gold (Au). For example, the preliminary conductive filler 221P may include copper (Cu) or a combination of copper (Cu) and nickel (Ni). The preliminary conductive filler 221P may be in contact with the top surface of the conductive via 211 to be electrically connected to the conductive via 211.

Thereafter, the preliminary first semiconductor chip 120P may be mounted on the first package substrate 110. The preliminary first semiconductor chip 120P may be attached to the first package substrate 110 such that the first chip pad 121 of the preliminary first semiconductor chip 120P faces the top surface of the first package substrate 110. The preliminary first semiconductor chip 120P may be formed in the cavity CV of the support substrate 200, and the sidewall of the preliminary first semiconductor chip 120P may be apart from the sidewall of the support substrate 200. The first chip pad 121 of the preliminary first semiconductor chip 120P may be electrically connected to the upper pad 117 of the first package substrate 110 through a chip connection terminal 123.

In some implementations, the conductive via 211 or the preliminary conductive filler 221P may be formed after the preliminary first semiconductor chip 120P is mounted on the first package substrate 110.

In some implementations, the first package substrate 110 may have a PCB strip structure, in which a plurality of PCBs are connected, and a plurality of preliminary first semiconductor chips 120P may be mounted on the first package substrate 110.

In some implementations, a vertical height of the preliminary first semiconductor chip 120P may be greater than 50 micrometers and a vertical height of the preliminary conductive filler 221P may be greater than 40 micrometers.

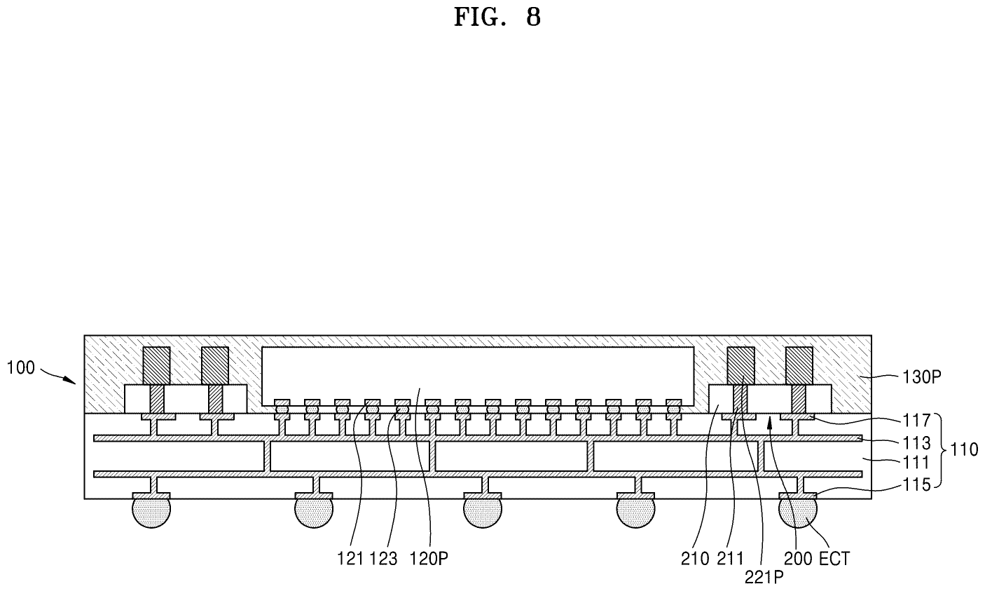

Referring to FIG. 8, a preliminary lower molding layer 130P may be formed to cover the preliminary first semiconductor chip 120P. The preliminary lower molding layer 130P may be formed on the top surface of the first package substrate 110 to cover the preliminary first semiconductor chip 120P and the preliminary conductive filler 221P. The preliminary lower molding layer 130P may be formed through compression molding. In some implementations, the preliminary lower molding layer 130P may be formed through a molded underfill process to fill the gap between the preliminary first semiconductor chip 120P and the first package substrate 110. Although not show, an underfill may be further formed through a capillary underfill process to surround the chip connection terminal 123. The underfill may be formed by filling the gap between the preliminary first semiconductor chip 120P and the first package substrate 110 with underfill resin to surround the chip connection terminal 123 between the preliminary first semiconductor chip 120P and the first package substrate 110.

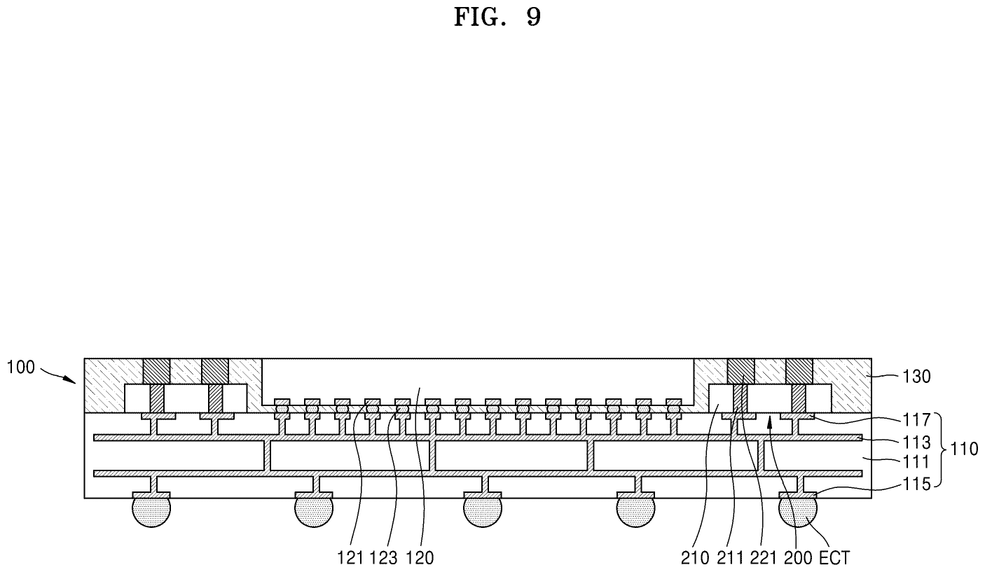

Referring to FIG. 9, planarization may be performed on the top surface of the resultant structure of FIG. 8. The planarization may include a grinding process, an etch back process, or a chemical mechanical polishing (CMP) process. The grinding process may be performed by strip grinding. A portion of the preliminary first semiconductor chip 120P (FIG. 8) may be removed by the planarization so that the first semiconductor chip 120 may be formed. In addition, a portion of the preliminary conductive filler 221P may be removed so that a conductive filler 221 may be formed. Due to the planarization, the top surface of the first semiconductor chip 120 and the top surface of the conductive filler 221 may be exposed.

In some implementations, the planarization may be performed such that the vertical height of the first semiconductor chip 120 is about 30 micrometers to about 50 micrometers and the vertical height of the conductive filler 221 is about 20 micrometers to about 40 micrometers.

Due to the planarization, the top surface of the first semiconductor chip 120, the top surface of the conductive filler 221, and the top surface of the lower molding layer 130 may be substantially coplanar with one another.

Because the top surface of each of the first semiconductor chip 120, the lower molding layer 130, and the conductive filler 221 have planarized surfaces resulting from the planarization, the surface roughness of the top surface of each of the first semiconductor chip 120, the lower molding layer 130, and the conductive filler 221 may be greater than that of the other surface of each of the first semiconductor chip 120, the lower molding layer 130, and the conductive filler 221. Accordingly, an adhesive strength between each of the first semiconductor chip 120, the lower molding layer 130, and the conductive filler 221 and an element to be formed on each of the first semiconductor chip 120, the lower molding layer 130, and the conductive filler 221 may increase.

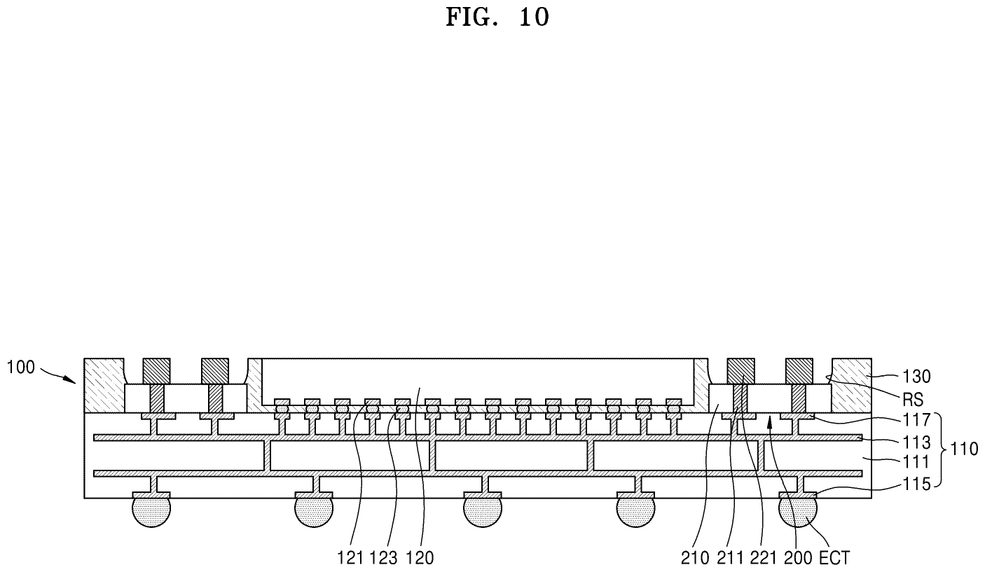

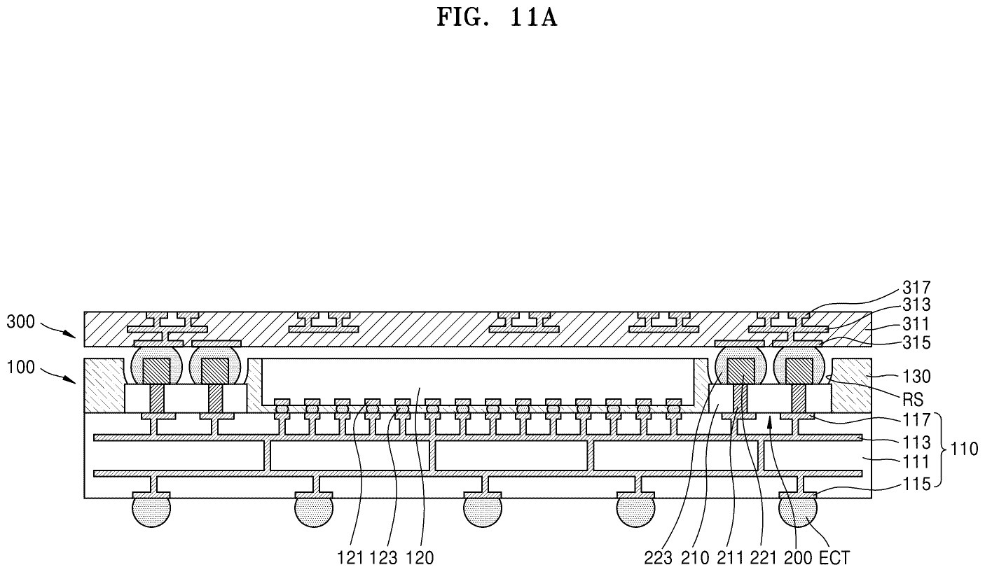

Referring to FIG. 10, a recess RS may be formed by etching a portion of the lower molding layer 130 around the conductive filler 221 in the resultant structure of FIG. 9. An etching process for forming the recess RS may include a laser drilling process. The recess RS may be formed to expose the conductive filler 221 surrounded by the lower molding layer 130. The sidewall of the conductive filler 221 may be exposed by the recess RS. Although it is illustrated that a portion of the top surface of the support substrate 200 is exposed by the recess RS, the portion of the top surface of the support substrate 200 may not be exposed. Although it is illustrated that the recess RS has a round sidewall, the shape of the recess RS is not limited thereto. For example, the recess RS may have an oblique sidewall. The sidewall of the recess RS may be apart from the sidewall of the conductive filler 221 and may be between the sidewall of the first semiconductor chip 120 and the sidewall of the conductive filler 221.

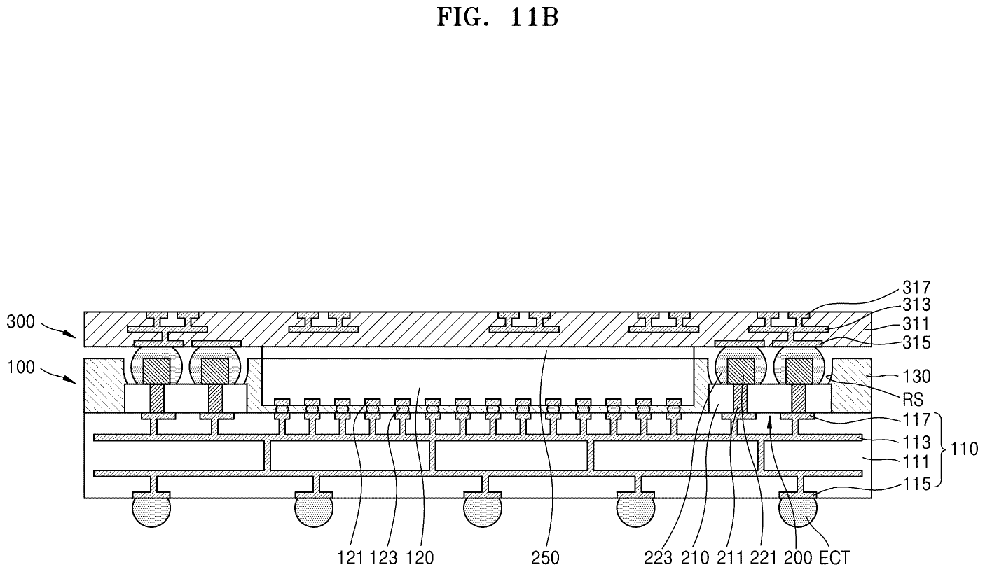

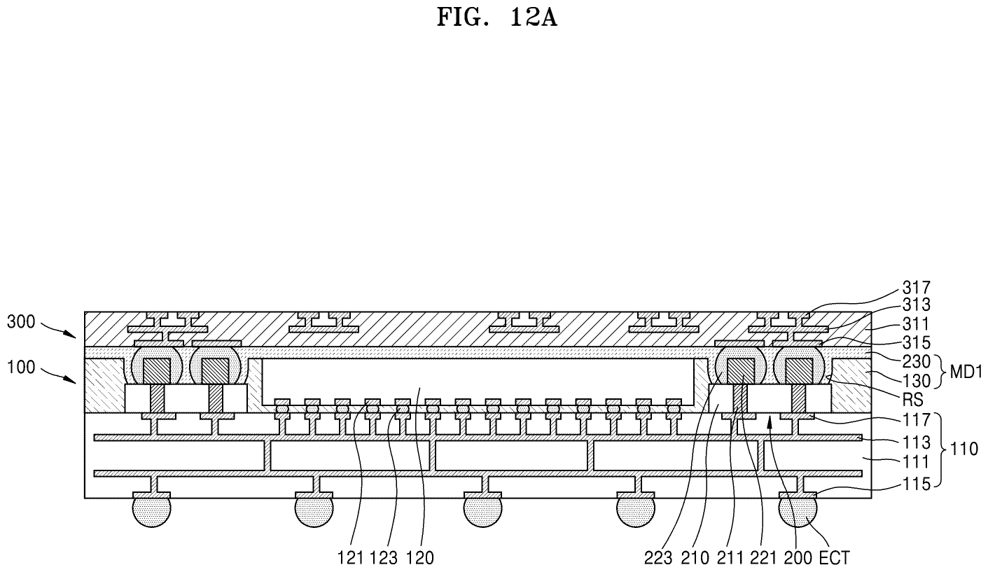

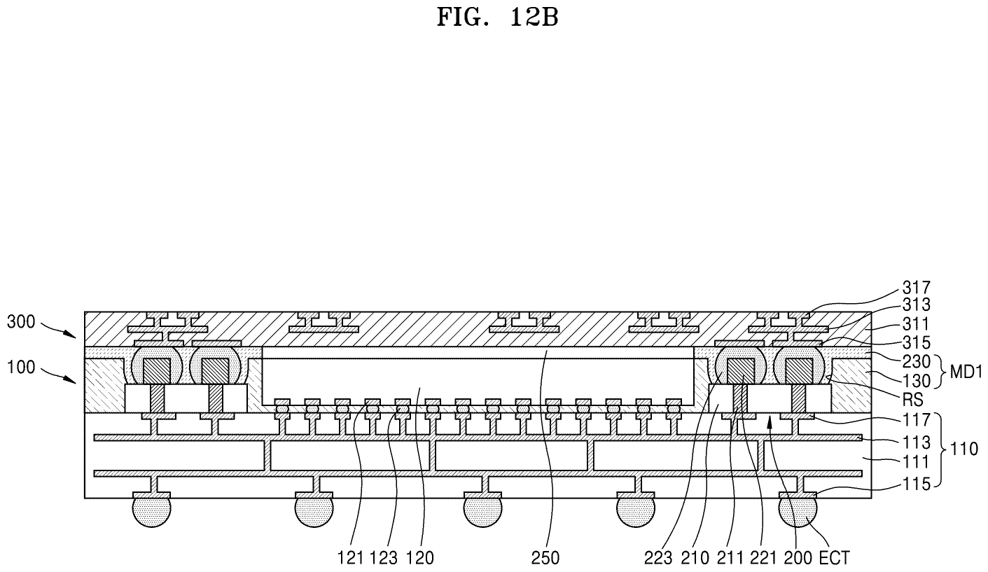

Subsequent processes for the semiconductor package 10 of FIG. 1A are described below with reference to FIGS. 11A and 12A and subsequent processes for the semiconductor package 30 of FIG. 3 are described below with reference to FIGS. 11B and 12B.

Referring to FIG. 11A, the interposer 300 may be arranged on the resultant structure of FIG. 10. A connection bump 223 may be formed to connect the interposer 300 to the resultant structure of FIG. 10. The connection bump 223 may fill at least a portion of the recess RS to surround the conductive filler 221. In some implementations, it is illustrated that the connection bump 223 is apart from the sidewall of the recess RS. However, the connection bump 223 may be in contact with at least a portion of the sidewall of the recess RS. The connection bump 223 may cover the sidewall and top surface of the conductive filler 221.

After the interposer 300 is arranged on the resultant structure of FIG. 10, a reflow process may be performed such that the connection bump 223 adheres to an interposer lower pad 315 of the interposer 300. During the reflow process, a material of the connection bump 223 may be melted into a liquid state and then hardened such that the connection bump 223 may be in contact with the interposer lower pad 315 of the interposer 300.

Due to the connection bump 223, there may be a gap between the top surface of the first semiconductor chip 120 and the bottom surface of the interposer 300.

The connection bump 223 may include a conductive material, e.g., solder, to electrically connect the conductive filler 221 to the interposer lower pad 315 of the interposer 300. In some implementations, the connection bump 223 may include a solder ball. In some implementations, the connection bump 223 may include a different material than the conductive filler 221.

In some implementations, when the first package substrate 110 has a PCB strip structure, a plurality of interposers 300 may be arranged on a plurality of first semiconductor chips 120 on the first package substrate 110.

Referring to FIG. 11B, the interposer 300 may be arranged on the resultant structure of FIG. 10. A connection bump 223 may be formed to connect the interposer 300 to the resultant structure of FIG. 10. The connection bump 223 may fill at least a portion of the recess RS to surround the conductive filler 221. In some implementations, it is illustrated that the connection bump 223 is apart from the sidewall of the recess RS. However, the connection bump 223 may be in contact with at least a portion of the sidewall of the recess RS. The connection bump 223 may cover the sidewall and top surface of the conductive filler 221.

After the interposer 300 is arranged on the resultant structure of FIG. 10, a reflow process may be performed such that the connection bump 223 adheres to an interposer lower pad 315 of the interposer 300. During the reflow process, a material of the connection bump 223 may be melted into a liquid state and then hardened such that the connection bump 223 may be in contact with the interposer lower pad 315 of the interposer 300.

The connection bump 223 may include a conductive material, e.g., solder, to electrically connect the conductive filler 221 to the interposer lower pad 315 of the interposer 300. In some implementations, the connection bump 223 may include a solder ball. In some implementations, the connection bump 223 may include a different material than the conductive filler 221.

In some implementations, when the first package substrate 110 has a PCB strip structure, a plurality of interposers 300 may be arranged on a plurality of first semiconductor chips 120 on the first package substrate 110.

A heat transfer material layer 250 may be further formed between the top surface of the first semiconductor chip 120 and the bottom surface of the interposer 300. The heat transfer material layer 250 may fill at least a portion of the gap between the top surface of the first semiconductor chip 120 and the bottom surface of the interposer 300. In some implementations, the heat transfer material layer 250 may be formed by attaching a prepared heat transfer material to the bottom surface of the interposer 300. In some implementations, the heat transfer material layer 250 may be formed by attaching a prepared heat transfer material to the top surface of the first semiconductor chip 120. The heat transfer material may include a polymer material having a high thermal conductivity. In some implementations, the heat transfer material layer 250 may include, but not limited to, a thermal conductive adhesive tape, thermal conductive grease, a thermal conductive interface pad, or a thermal conductive adhesive.

Referring to FIG. 12A, the upper molding layer 230 may be formed between the top surface of the first semiconductor chip 120 and the bottom surface of the interposer 300. The upper molding layer 230 may be formed by a transfer molding process. The upper molding layer 230 may be formed by applying temperature or pressure to a molding material for the upper molding layer 230 and then implanting the molding material into the gap between the top surface of the first semiconductor chip 120 and the bottom surface of the interposer 300.

The upper molding layer 230 may fill at least a portion of the gap between the top surface of the first semiconductor chip 120 and the bottom surface of the interposer 300. The upper molding layer 230 may fill at least a portion of the gap between the top surface of the first semiconductor chip 120 and the bottom surface of the interposer 300 and then extend to fill at least a portion of the recess RS of the lower molding layer 130. In detail, the upper molding layer 230 may fill a portion of the recess RS, which is not filled with the lower molding layer 130. The upper molding layer 230 may cover the top surface of the first semiconductor chip 120, the top surface of the lower molding layer 130, the sidewall of the recess RS, and the bottom of the recess RS (e.g., the top surface of the support substrate 200 that is exposed by the recess RS).

Accordingly, the first molding layer MD1 may be formed to surround the connection bump 223. The first molding layer MD1 may be in contact with the sidewall of the connection bump 223 and may fix the connection bump 223.

Thereafter, singulation may be carried out along a scribe lane by using a sawing blade, thereby forming individual semiconductor packages.

Referring to FIG. 12B, the upper molding layer 230 may be formed between the top surface of the lower molding layer 130 and the bottom surface of the interposer 300. The upper molding layer 230 may be formed by a transfer molding process. The upper molding layer 230 may be formed by applying temperature or pressure to a molding material for the upper molding layer 230 and then implanting the molding material into the gap between the top surface of the lower molding layer 130 and the bottom surface of the interposer 300.

The upper molding layer 230 may fill at least a portion of the gap between the top surface of the lower molding layer 130 and the bottom surface of the interposer 300. The upper molding layer 230 may fill at least a portion of the gap between the top surface of the lower molding layer 130 and the bottom surface of the interposer 300 and then extend to fill at least a portion of the recess RS of the lower molding layer 130. In detail, the upper molding layer 230 may fill a portion of the recess RS, which is not filled with the connection bump 223. The upper molding layer 230 may fill at least a portion of the gap between the top surface of the lower molding layer 130 and the bottom surface of the interposer 300 and then extend to fill at least a portion of the gap between the first semiconductor chip 120 and the bottom surface of the interposer 300. In detail, the upper molding layer 230 may fill a portion of the gap between the first semiconductor chip 120 and the bottom surface of the interposer 300, which is not filled with the heat transfer material layer 250.

The upper molding layer 230 may cover a portion of the top surface of the first semiconductor chip 120, which is not covered with the heat transfer material layer 250, the top surface of the lower molding layer 130, the sidewall of the recess RS, and the bottom of the recess RS (e.g., the top surface of the support substrate 200 that is exposed by the recess RS).

Accordingly, the first molding layer MD1 may be formed to surround the connection bump 223. The first molding layer MD1 may be in contact with the sidewall of the connection bump 223 and may fix the connection bump 223.

Thereafter, singulation may be carried out along a scribe lane by using a sawing blade, thereby forming individual semiconductor packages.

According to some implementations, because the sidewall and top surface of the conductive filler 221 are surrounded by the connection bump 223, detachment between the conductive filler 221 and the connection bump 223 may be prevented, and therefore, a semiconductor package having improved reliability may be provided. In addition, because the sidewall of the connection bump 223 is surrounded by the first molding layer MD1, detachment between the connection bump 223 and the interposer lower pad 315 may be prevented, and therefore, a semiconductor package having improved reliability may be provided.

When the heat transfer material layer 250 is further formed, the performance of the first semiconductor chip 120 may be prevented from degrading due to the heat transfer material layer 250, and accordingly, a semiconductor package having an improved heat dissipation characteristic may be provided.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been shown and described with reference to implementations thereof, it will be understood that various changes in form and details may be made therein without departing from the spirit and scope of the following claims.

What is claimed is:

1. A semiconductor package comprising:
a first package substrate;
a first semiconductor chip on the first package substrate;
an interposer on the first semiconductor chip;
a support substrate on the first package substrate, the support substrate being spaced apart from a sidewall of the first semiconductor chip;
a conductive filler on the support substrate;
a connection bump between the support substrate and the interposer, the connection bump configured to electrically connect the conductive filler with the interposer; and
a first molding layer configured to surround the sidewall of the first semiconductor chip and a sidewall of the connection bump.

2. The semiconductor package of claim 1, wherein
a bottom surface of the interposer is spaced apart from a top surface of the first semiconductor chip, and
the first molding layer is configured to fill at least a portion of a gap between the top surface of the first semiconductor chip and the bottom surface of the interposer.

3. The semiconductor package of claim 1, wherein a surface roughness of a top surface of the first semiconductor chip is greater than a surface roughness of the sidewall of the first semiconductor chip.

4. The semiconductor package of claim 1, wherein the connection bump includes a material different from a material of the conductive filler.

5. The semiconductor package of claim 1, wherein the connection bump is configured to surround a sidewall and a top surface of the conductive filler.

6. The semiconductor package of claim 1, wherein
the first molding layer includes a lower molding layer and an upper molding layer,
each molding layer of the lower molding layer and the upper molding layer includes at least one of an epoxy molding compound (EMC), a filler, or a hardener, and
a ratio of the EMC, the filler, and the hardener in the lower molding layer is different from a ratio of the EMC, the filler, and the hardener in the upper molding layer.

7. The semiconductor package of claim 1, wherein
the first molding layer includes:
a lower molding layer defining a recess; and
an upper molding layer configured to fill at least a portion of the recess, and the conductive filler is positioned at the recess.

8. The semiconductor package of claim 1, wherein
the first molding layer includes:
a lower molding layer defining a recess including a first portion and a second portion; and
an upper molding layer on the lower molding layer,
the conductive filler and the connection bump are filled with the first portion of the recess, and
the upper molding layer is configured to fill the second portion of the recess.

9. The semiconductor package of claim 1, comprising:
a second package substrate on the interposer;
a second semiconductor chip on the second package substrate; and
a second molding layer configured to surround a sidewall of the second semiconductor chip.

10. The semiconductor package of claim 1, wherein
the support substrate includes:
a support substrate base; and
a conductive via configured to pass through the support substrate base and to electrically connect the conductive filler with the first package substrate.

11. A semiconductor package comprising:
a first package substrate;
a first semiconductor chip on the first package substrate;
an interposer on the first semiconductor chip;
a heat transfer material layer configured to fill at least a portion of a gap between a bottom surface of the interposer and a top surface of the first semiconductor chip;
a support substrate on the first package substrate, the support substrate being spaced apart from a sidewall of the first semiconductor chip;
a conductive filler on the support substrate;
a connection bump between the support substrate and the interposer, the connection bump configured to surround a sidewall and a top surface of the conductive filler; and
a first molding layer configured to surround the sidewall of the first semiconductor chip and a sidewall of the connection bump.

12. The semiconductor package of claim 11, wherein the first molding layer is configured to surround a sidewall of the heat transfer material layer.

13. The semiconductor package of claim 11, wherein
a sidewall of the heat transfer material layer is spaced apart from the sidewall of the connection bump, and
the first molding layer is configured to fill at least a portion of a gap between the sidewall of the heat transfer material layer and the sidewall of the connection bump.

14. The semiconductor package of claim 11, wherein
the first molding layer includes:
a lower molding layer configured to surround the sidewall of the first semiconductor chip; and
an upper molding layer configured to surround a sidewall of the heat transfer material layer.

15. The semiconductor package of claim 11, wherein
the heat transfer material layer includes at least one of a thermal conductive adhesive tape, thermal conductive grease, a thermal conductive interface pad, or a thermal conductive adhesive.

16. The semiconductor package of claim 11, comprising:
a second package substrate on the interposer;
a second semiconductor chip on the second package substrate; and
a second molding layer configured to surround a sidewall of the second semiconductor chip.

17. A semiconductor package comprising:
a first package substrate;
a first semiconductor chip on the first package substrate;
an interposer on the first semiconductor chip;
a support substrate on the first package substrate, the support substrate being spaced apart from a sidewall of the first semiconductor chip;
a conductive filler on the support substrate;
a connection bump between the support substrate and the interposer, the connection bump configured to surround a sidewall and a top surface of the conductive filler and to electrically connect the conductive filler with the interposer;
a first molding layer configured to surround the sidewall of the first semiconductor chip and a sidewall of the connection bump, the first molding layer being in contact with at least a portion of the sidewall of the connection bump;
a second package substrate on the interposer;
a second semiconductor chip on the second package substrate; and
a second molding layer configured to surround a sidewall of the second semiconductor chip.

18. The semiconductor package of claim 17, wherein
a bottom surface of the interposer is spaced apart from a top surface of the first semiconductor chip, and
the first molding layer is configured to fill at least a portion of a gap between the top surface of the first semiconductor chip and the bottom surface of the interposer.

19. The semiconductor package of claim 17, wherein
a bottom surface of the interposer is spaced apart from a top surface of the first semiconductor chip, and
the semiconductor package comprises a heat transfer material layer configured to fill at least a portion of a gap between the top surface of the first semiconductor chip and the bottom surface of the interposer.

20. The semiconductor package of claim 17, wherein
the support substrate includes:
a support substrate base; and
a conductive via configured to pass through the support substrate base and to electrically connect the conductive filler with the first package substrate.
